(19) United States
(12) Patent Application Publication
(10) Pub. No.: US 2022/0208714 A1
(43) Pub. Date: Jun. 30, 2022

(54) INTEGRATED CIRCUIT PACKAGE STRUCTURE, INTEGRATED CIRCUIT PACKAGE UNIT AND ASSOCIATED PACKAGING METHOD

(71) Applicant: Chengdu Monolithic Power Systems Co., Ltd., Chengdu (CN)

(72) Inventors: Yingjiang Pu, Chengdu (CN); Hunt Hang Jiang, Saratoga, CA (US)

(21) Appl. No.: 17/468,527

(22) Filed: Sep. 7, 2021

(30) Foreign Application Priority Data
Sep. 10, 2020 (CN) 202010944603.2

(51) Int. Cl. H01L 23/00; H01L 23/373; H01L 23/367; H01L 23/31; H01L 21/56; H01L 21/48

(52) U.S. Cl. CPC H01L 24/20; H01L 23/3736; H01L 23/367; H01L 23/3185; H01L 24/19; H01L 2224/214; H01L 21/4814; H01L 2224/2101; H01L 2224/2105; H01L 2224/211; H01L 21/56

(57) ABSTRACT

An IC package structure and associated packaging method. The IC package structure may include an array of package units formed into a panel, wherein each one of the array of package units comprises at least one IC chip/IC die. Each IC chip/IC die may be at least partially covered and wrapped by an encapsulation layer having one or more openings to expose entire or at least a portion of a back surface of each IC chip/IC die. A metal layer may be electroplated on entire back side of the IC package structure to fill the openings in the encapsulation layer so that the metal layer is in direct contact with the exposed portions of the back surface of each IC chip/IC die.

### CROSS-REFERENCE TO RELATED APPLICATION(S)

This application claims the benefit of CN application No. 202010944603.2 filed on Sep. 10, 2020 and incorporated herein by reference.

### TECHNICAL FIELD

This disclosure relates generally to semiconductor devices, and particularly but not exclusively relates to packaging structure for integrated circuit and associated packaging method.

### BACKGROUND

To integrate more integrated circuits and circuit elements on smaller integrated circuit board or system board (i.e. increasing integration density) becomes an important trend in integrated circuit development. Integrated circuits can generally be packaged into integrated circuit chips that can be soldered/mounted/inserted on circuit board or system board. The integrated circuit chips typically have I/O pins or conductive bumps allowing them to make electrical connection and/or signal communication with other outside circuits. To improve integration density, it is desired to further shrink the package size of integrated chips. However, with the increase in integration density, thermal dissipation performance should also be improved.

### SUMMARY

In accordance with an embodiment of the present disclosure, an IC package structure is disclosed. The IC package structure may comprise: an array of package units formed into a panel, wherein each one of the array of package units comprises at least one IC chip/IC die, and wherein each IC chip/IC die has a top surface and a back surface opposite to the top surface; an encapsulation layer, filling gaps between the package units, at least partially covering and wrapping the at least one IC chip/IC die in each package unit, and having one or more openings at a portion corresponding to the back surface of each IC chip/IC die to expose entire or at least a portion of the back surface of each IC chip/IC die; and a metal layer, electroplated on entire back side of the IC package structure and filling the openings in the encapsulation layer so that the metal layer is in direct contact with the exposed portions of the back surface of each IC chip/IC die, wherein the back side of the IC package structure refers to the side to which the back surface of the IC chip/IC die is facing.

In accordance with an embodiment of the present disclosure, an IC package unit is disclosed. The IC package unit may comprise: at least one IC chip/IC die, each of at least one IC chip/IC die having a top surface and a back surface opposite to the top surface; an encapsulation layer, filling the IC package unit to at least partially cover and wrap the at least one IC chip/IC die, and having one or more openings at a portion corresponding to the back surface of each IC chip/IC die to expose entire or at least a portion of the back surface of each IC chip/IC die; and a metal layer, electroplated on entire back side of the IC package unit and filling the openings in the encapsulation layer so that the metal layer is in direct contact with the exposed portions of the back surface of each IC chip/IC die, wherein the back side of the IC package unit refers to the side to which the back surface of the IC chip/IC die is facing.

In accordance with an embodiment of the present disclosure, a method for manufacturing an integrated circuit (“IC”) package structure is disclosed. The method may comprise: attaching a plurality of IC chips/IC dies to be packaged on a carrier; forming an encapsulation layer to fill gaps/spaces between the plurality of IC chips/IC dies, and cover and wrap the plurality of IC chips/IC dies; removing at least a portion of the encapsulation layer above each IC chip/IC die to form one or more openings to expose entirety or at least a portion of a back surface of each IC chip/IC die; forming a seed layer on the encapsulation layer and the exposed portions of the back surface of each IC chip/IC die; and electroplating metal materials on the seed layer to form a metal layer which is in direct contact with the exposed portions of the back surface of each IC chip/IC die.

### BRIEF DESCRIPTION OF THE DRAWINGS

The following detailed description of various embodiments of the present invention can best be understood when read in conjunction with the following drawings, in which the features are not necessarily drawn to scale but rather are drawn as to best illustrate the pertinent features. Likewise, the relative sizes of elements illustrated by the drawings may differ from the relative size depicted.

FIG. 1A illustrates a top plane view of an integrated circuit (“IC”) package structure 100 in accordance with an embodiment of the present invention.

FIG. 1B illustrates a cross-sectional (cutting down along the Z-axis direction) view of a portion of the IC package structure 100 in accordance with an embodiment of the present invention.

FIG. 1C illustrates a cross-sectional (cutting down along the Z-axis direction) view of another portion of the IC package structure 100 shown in FIG. 1A, which can be considered as a partial cross-sectional view corresponding to the portion cutting along the B-B′ cutting line of FIG. 1A.

FIG. 1D illustrates a cross-sectional (cutting down along the Z-axis direction) view of a portion of the IC package structure 100 in accordance with an alternative embodiment of the present invention.

FIG. 1E illustrates a cross-sectional (cutting down along the Z-axis direction) view of a portion of the IC package structure 100 in accordance with an alternative embodiment of the present invention.

FIG. 2A to FIG. 2F illustrate partial cross-sectional views of some process stages of a method for manufacturing an integrated circuit (“IC”) package structure in accordance with an embodiment of the present invention.

The use of the same reference label in different drawings indicates the same or like components or structures with substantially the same functions for the sake of simplicity.

### DETAILED DESCRIPTION

Various embodiments of the present invention will now be described. In the following description, some specific details, such as example device structures, example manufacturing process and manufacturing steps, and example values for the process, are included to provide a thorough understanding of the embodiments. One skilled in the relevant art will recognize, however, that the present invention can be practiced without one or more specific details, or with other methods, components, materials, etc. In other instances, well-known structures, materials, processes or operations are not shown or described in detail to avoid obscuring aspects of the present invention.

Throughout the specification and claims, the terms “left,” right,” “in,” “out,” “front,” “back,” “up,” “down, “top,” “atop”, “bottom,” “over,” “under,” “overlying,” “underlying,” “above,” “below” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The term “coupled,” as used herein, is defined as directly or indirectly connected in an electrical or non-electrical manner to establish an electrical relationship between the elements that are coupled. The terms “a,” “an,” and “the” includes plural reference, and the term “in” includes “in” and “on”. The phrase “in one embodiment,” as used herein does not necessarily refer to the same embodiment, although it may. The term “or” is an inclusive “or” operator, and is equivalent to the term “and/or” herein, unless the context clearly dictates otherwise. Those skilled in the art should understand that the meanings of the terms identified above do not necessarily limit the terms, but merely provide illustrative examples for the terms.

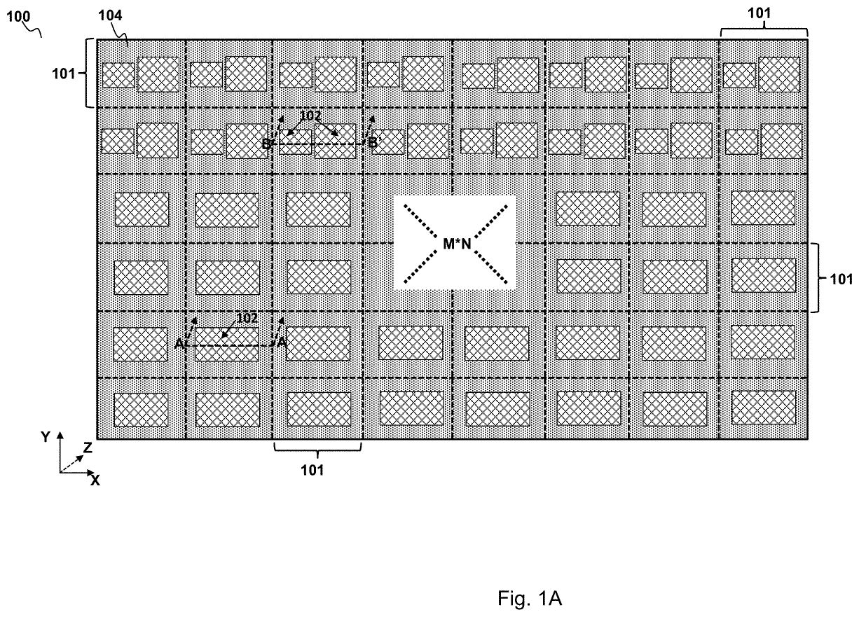

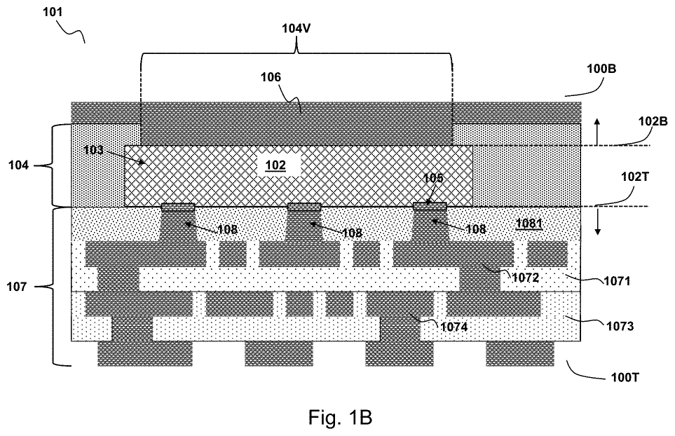

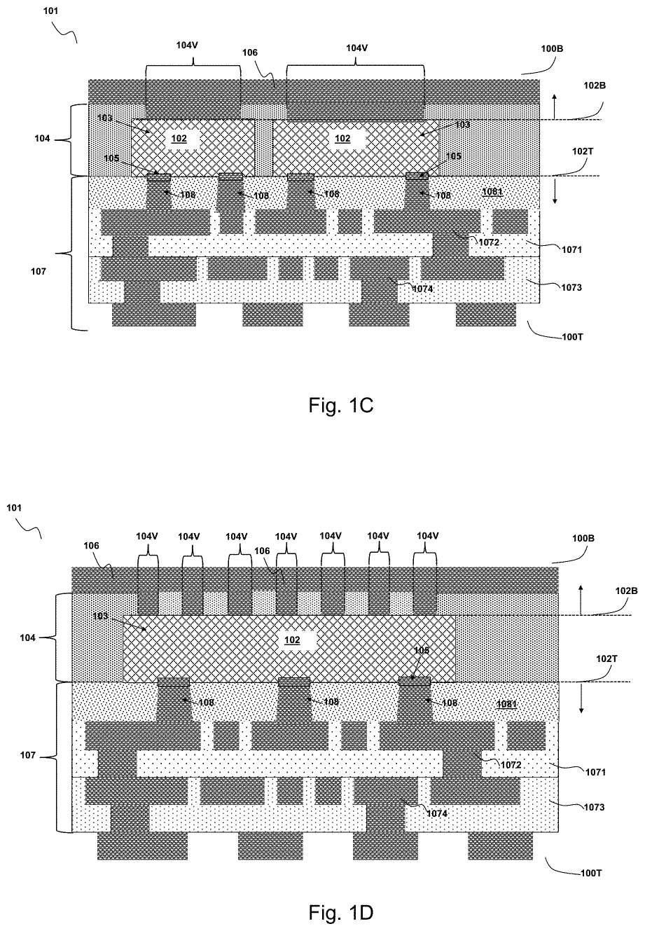

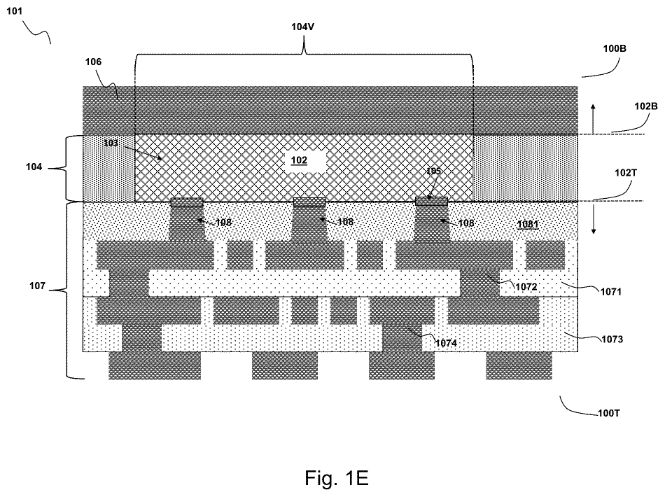

FIG. 1A illustrates a top plane view of an integrated circuit (“IC”) package structure 100 in accordance with an embodiment of the present invention. In FIG. 1A, the top plane view of IC package structure 100 may be considered as taken from the X-Y plane defined by the X and Y axis in a coordinate defined by X, Y and Z axis perpendicular to each other. In the exemplary embodiment of FIG. 1A, the IC package structure 100 may comprise an array of package units 101 formed into a panel. The boundaries of the package units 101 are illustrated in dashed lines. One of ordinary skill in the art would understand that the area of each package unit 101 illustrated in FIG. 1A is indicative of a single package unit 101 that would be singulated in the Z axis. Although the panel of IC package structure 100 (or the panel of the array of package units 101) in FIG. 1A is exemplarily illustrated as of rectangular shape (here refers to the top plane view shape on the X-Y plane), it should be understood by those skilled in the art that this is only an example and not intended to be limiting. In alternative embodiments, the panel of IC package structure 100 (or the panel of the array of package units 101) may be of other shapes such as circular, polygonal, or other shapes that are compatible with the manufacturing process. This application does not limit the panel size (here refers to the size on the X-Y plane) of the panel of IC package structure 100 (or the panel of the array of package units 101). For example, for a rectangular panel, the panel size may be chosen from 300 mm*300 mm, 580 mm*600 mm, 800 mm*800 mm, 240 mm*74 mm, 189 mm*68 mm and many other sizes that are compatible with the manufacturing process. The array of the package unit 101 may be an array arrangement of any suitable number and shape (here refers to the top view shape on the X-Y plane). As an example, FIG. 1A illustrates a rectangular array of M rows by N columns, wherein M and N are both positive integers greater than or equal to 1. Cutting/singulating such a panel of IC package structure 100 having an array of M*N packaging units 101 along the Z axis with the package unit 101 as a cutting unit will obtain M*N singulated individual package units 101. Those skilled in the art should understand that most of the detailed structure of each package unit 101 is not shown in the top plan view of FIG. 1A.

FIG. 1B illustrates a cross-sectional (cutting down along the Z-axis direction) view of a portion of the IC package structure 100 in accordance with an embodiment of the present invention. The cross-section in FIG. 1B may be considered as a partial cross-sectional view corresponding to a portion cutting along the A-A′ cutting line in the Z-axis of FIG. 1A. Each one of the package units 101 in the IC package structure 100 may comprise at least one IC chip/IC die 102 molded or encapsulated by an encapsulation layer 104 (for example formed of an epoxy resin molding compound or other appropriate encapsulation materials). The encapsulation layer 104 may fill the gaps between the package units 101 in the array of the package units 101, cover and wrap the IC chip(s)/IC die(s) 102 in each package unit 101, and electrically isolate the integrated circuit chips or dies 102 from each other. It also plays a role in preventing moisture and shaping the entire panel of the IC package structure 100, and so on. In the example of FIG. 1B showing the package unit 101 in the cross-sectional view cut along the A-A′ cutting line in FIG. 1A includes one IC chip/IC die 102. Those skilled in the art should understand that, in other embodiments or along other cutting lines, the package unit 101 shown by cross-sectional cutting in other portions of FIG. 1A may include two or more IC chips/IC dies 102. For example, FIG. 1C illustrates a cross-sectional (cutting down along the Z-axis direction) view of another portion of the IC package structure 100 shown in FIG. 1A, which can be considered as a partial cross-sectional view corresponding to the portion cutting along the B-B′ cutting line of FIG. 1A. The package unit 101 shown in the example of FIG. 1C includes two integrated circuit chips/dies 102. The number and arrangement pattern or stacking fashion of the IC chips/IC dies 102 packaged in different package units 101 can be different. The size of each IC chip/IC die 102 and the circuit functions implemented can be the same or different, depending on the specific circuit functions to be implemented by a single package unit 101.

Each IC chip/IC die 102 may comprise a substrate 103 on or in which integrated circuits are fabricated. Those skilled in the art should understand that the substrate 103 may comprise substrate formed of semiconductor materials such as silicon (Si), compound semiconductor materials such as silicon germanium (SiGe), or other forms of substrates such as silicon-on-insulator (SOI). The integrated circuit(s) fabricated on or in the substrate 103 may allow connection or coupling to circuits outside the IC chip/IC die 102 through a plurality of metal pads 105. The surface of the IC chip/IC die 102 on which the metal pads 105 are formed can be referred to as a top surface (labeled with 102T in FIG. 1B), and the surface opposite to the top surface 102T can be referred to as a back surface (labeled with 102B in FIG. 1B). Correspondingly, for the IC package structure 100 and each package unit 101, the side (for example, the direction indicated by the downward arrow in FIG. 1B) to which the top surface 102T of the IC chip/IC die 102 is facing can be referred to as a top side (indicated with 100T in FIG. 1B) of the IC package structure 100 or of each package unit 101, and the side to which the back surface 102B of the IC chip/IC die 102 faces (for example, the direction indicated by upward arrow in FIG. 1B) can be referred to as a back side (indicated with 100B in FIG. 1B) of the IC package structure 100 or of each package unit 101.

The encapsulation layer 104 may have one or more openings 104V at a portion corresponding to the back surface 102B of each IC chip/IC die 102, exposing entire or at least a portion of the back surface 102B of each IC chip/IC die 102. The exemplary embodiments of this disclosure do not limit the shape, size, and number of the one or more openings 104V. For example, according to the illustration in FIG. 1B and FIG. 1C, those skilled in the art would understand that a relatively large opening 104V can be formed in portions of the encapsulation layer 104 above each IC chip/IC die 102, which may expose entire or most of the back surface 102B of each IC chip/IC die 102. FIG. 1D illustrates an alternative example. In FIG. 1D, a plurality of relatively small openings 104V may be formed in portions of the encapsulation layer 104 above each IC chip/IC die 102, exposing a corresponding plurality of portions (corresponding to the plurality of openings 104V) of the back surface 102B of each IC chip/IC die 102. FIG. 1E illustrates another alternative example. In FIG. 1E, the entire back surface of the encapsulation layer 104 can be grounded/polished (for example, with chemical grinding and/or mechanical grinding, etc.), until the entire back surface 102B of the IC chip/IC die 102 is exposed.

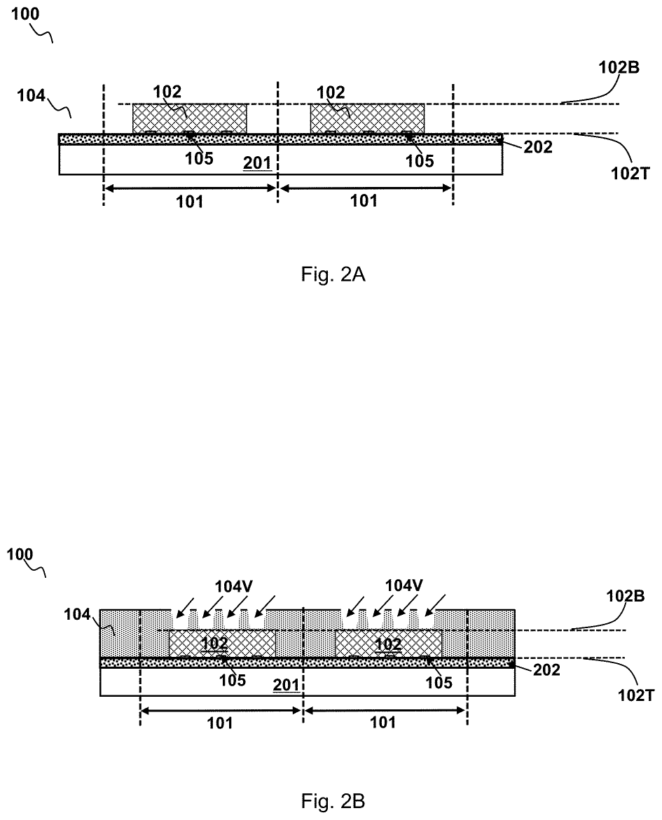

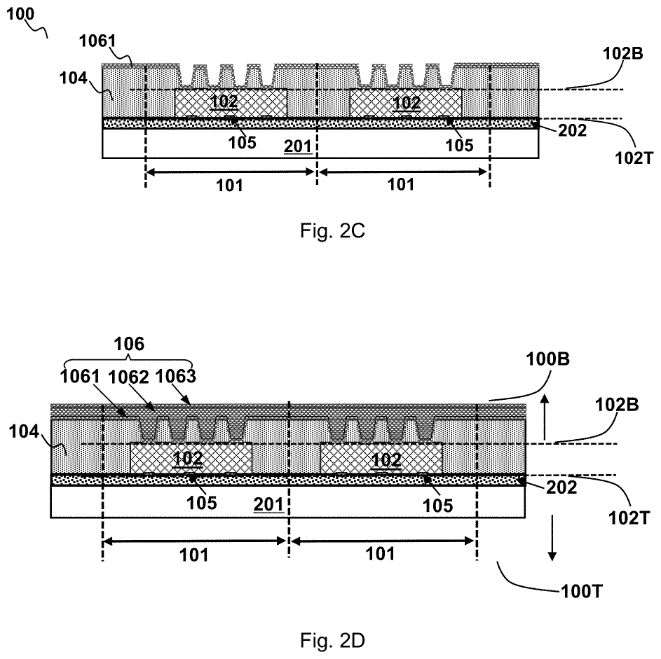

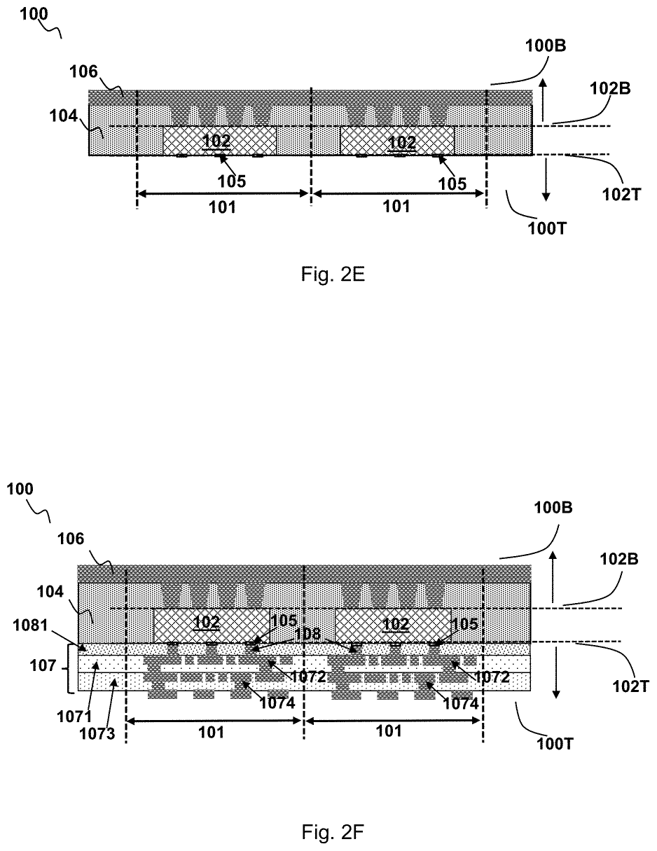

In accordance with the exemplary embodiments of FIG. 1A to FIG. 1E, the IC package structure 100 may further comprise a metal layer 106 fabricated on the entire back side 100B of the IC package structure 100 by an electroplating process and filling the openings 104V, so that the metal layer 106 is in direct contact with the exposed portions of the back surface 102B of each IC chip/IC die 102 (i.e., the portions of the back surface 102B of each IC chip/IC die 102 that are not covered by the encapsulation layer 104). The metal layer 106 may be formed by electroplating metal materials such as copper, nickel, and/or gold etc. Since the metal layer 106 is electroplated, during the electroplating process, molecular bonding forms at the interface between the metal layer 106 and the back surface 102B of each IC chip/IC die 102. Such molecular bonding between the metal material of the metal layer 106 and the substrate material (e.g. typically semiconductor material) of the substrate 103 of each IC chip/IC die 102 can be very strong bond. And thus, the metal layer 106 may be tightly bonded to (not easy to fall off from) the back surface 102B of each IC chip/IC die 102, without the need to use any additional adhesive layer or adhesive material which is usually a resin material having a thermal conductivity far inferior to the metal layer 106. Therefore, forming the metal layer 106 on back side of the IC package structure 100 not only saves process costs, but the direct contact between the metal layer 106 and the back surface 102B of each IC chip/IC die 102 may help to greatly enhance the heat dissipation capacity of the IC chip/IC die 102, and improve the heat dissipation performance of each IC chip/IC die 102. In an embodiment, the metal layer 106 may comprise a seed layer 1061 (refer also to FIG. 2D for illustration), and a main metal layer 1062 (refer also to FIG. 2D for illustration) formed on the seed layer 1061. The main metal layer 1062 may comprise for instance a copper layer or a copper-nickel stack layer or other single metal layers or multilayer metal stacked layers). In one embodiment, the metal layer 106 may further comprise an anti-oxidation metal layer 1063 formed on the main metal layer 1062 (refer also to FIG. 2D for illustration, for example, an electroplated SUS alloy layer).

In accordance with an exemplary embodiment, the metal pads 105 (such as aluminum pads or copper pads) formed on the top surface 102T of each IC chip/IC die 102 may be the input/output (I/O) pads of the IC chip/IC die 102. In the examples illustrated in FIG. 1A to FIG. 1E, the metal pads 105 may be coupled to the package pins/solder bumps of the IC package structure 100 through a rewiring structure 107 to allow the IC chip/IC die 102 to be electrically coupled to external circuits or for signal communication. The rewiring structure 107 may comprise one or more interlayer dielectric layer(s) and one or more rewiring metal layer(s). For example, referring to the examples illustrated in FIG. 1A to FIG. 1E, the rewiring structure 107 may include metal pillars 108 passing/extending through a first interlayer dielectric layer 1081. For example, a plurality of metal pillars 108 may be formed corresponding to each IC chip/IC die 102 to facilitate electrical connection to the corresponding plurality of metal pads 105 of each IC chip/IC die 102. The plurality of metal pillars 108 may also be electrically connected to the rewiring metal layer(s) (for example, connected to the first rewiring metal layer 1072). The rewiring metal layers may include, for example, a first rewiring metal layer 1072 that passes/extends through a second interlayer dielectric layer 1071 and is electrically connected to the plurality of metal pillars 108. In some embodiments, the rewiring metal layer(s) may further include, for example, a second rewiring metal layer 1074, which passes/extends through a third interlayer dielectric layer 1073 to electrically connect to the first rewiring metal layer 1072. Those skilled in the art should understand that the first interlayer dielectric layer 1081, the second interlayer dielectric layer 1071, and the third interlayer dielectric layer 1073 may include the same dielectric material, or may include different dielectric materials. The rewiring structure 107 described here is just for example and not intended to be limiting.

FIG. 2A to FIG. 2F illustrate partial cross-sectional views of some process stages of a method for manufacturing an integrated circuit (“IC”) package structure (for example, the IC package structure 100 mentioned in the above described embodiments with reference to FIG. 1A to FIG. 1E) in accordance with an embodiment of the present invention.

Referring to the cross-sectional view illustrated in FIG. 2A, a plurality of IC chips/IC dies 102 to be packaged may be attached/adhered to a carrier 201 through an adhesive layer 202 (for example, a resin material that is easy to peel off, etc.). Those skilled in the art should understand that the shape and size of the carrier 201 may be reasonably selected according to the shape, size, quantity and so on of the IC chips/IC dies 102 to be packaged, which is not limited in this application. In the examples shown in FIG. 2A to FIG. 2F, the IC chips/IC dies 102 may comprise flip chip IC chips/IC dies, each having a top surface 102T with a plurality of metal pads 105 formed thereon and a back surface 102B opposite to the top surface 102T. A plurality of preset positions may be designated in advance on the carrier 201 for the plurality of the IC chips/IC dies 102 to be packaged in a one-to-one correspondence manner. Then the plurality of IC chips/IC dies 102 may be mounted on the carrier 201 in batches with the top surface 102T of each IC chip/IC die 102 facing down to the carrier 201 and mounted on a corresponding preset position on the carrier 201. Each one of the plurality of IC chips/IC dies 102 may be separated from other neighboring IC chips/IC dies 102 with a gap/space. Usually the plurality of IC chips/IC dies 102 may be packaged in batch through subsequent processes to form a panel level IC package structure (such as the IC package structure 100). The panel level IC package structure may at last be singulated or cut into multiple individual package units (such as package units 101), each singulated/individual package unit 101 may comprise at least one IC chip/IC die 102. For better understanding, one can also turn to the exemplary top plan view illustration in FIG. 1A for reference. In the exemplary cross-sectional view of FIG. 2A, boundaries of the package units 101 are illustrated in dashed lines.

Now turning to the cross-sectional view illustrated in FIG. 2B, an encapsulation layer 104 may be formed on the carrier 201. The encapsulation layer 104 may fill the gaps/spaces between the package units 101, cover and wrap the IC chip(s) or IC die(s) 102 in each package unit 101, and electrically isolate the integrated circuit chips or dies 102 from each other. It also plays a role in preventing moisture and shaping the entire panel of the IC package structure 100, and so on. After that, at least a portion of the encapsulation layer 104 may be removed to form one or more openings 104V to expose entirety or at least a portion of the back surface 102B of each IC chip/IC die 102. In the example of FIG. 2B, it is illustrated that a plurality of openings 104V are formed in the encapsulation layer 104 above the back surface 102B of each IC chip or IC die 102. However, those skilled in the art should understand that the exemplary embodiments of this disclosure do not limit the shape, size, and number of the openings 104V. For instance, more examples may be referred to the illustrations in FIG. 1B to FIG. 1E and corresponding descriptions in connection with these figures. There are many options for forming the openings 104V in the encapsulation layer 104, for example, laser polishing, chemical polishing, or mechanical polishing or one or more combinations thereof may be used.

Next, referring to FIG. 2C, a seed layer 1061 may be formed on the encapsulation layer 104 and the exposed back surface 102B of the IC chips or IC dies 102. The seed layer 1061 may be spread over the surface of the encapsulation layer 104 and the exposed back surface 102B (exposed by the plurality of openings 104V) of the IC chips or IC dies 102 for instance by sputtering conductive materials (such as titanium, copper, or other metals or alloys etc.). In an embodiment, the seed layer 1061 may comprise a titanium-copper (Ti—Cu) stack layer, wherein the titanium layer may be formed on the surface of the encapsulation layer 104 and the exposed back surface 102B of the IC chips or IC dies 102, and the copper layer may be formed on the titanium layer. In the titanium-copper (Ti—Cu) stack layer, the titanium layer may be used as a protective layer, and the copper layer may be used as an electroplating seed layer.

Next, referring to FIG. 2D, a metal layer 106 may be formed by electroplating metal materials (for example, copper, nickel, gold, or other metal or alloy etc.). In an exemplary embodiment, electroplating metal materials may comprise electroplating a copper layer or a copper-nickel stack layer or other single metal layers or multilayer metal stacked layers to form a main metal layer 1062. In an embodiment, electroplating metal materials may further comprise electroplating an anti-oxidation metal layer 1063 (for example, an SUS alloy layer) on the main metal layer 1062. The anti-oxidation metal layer 1063 may protect the main metal layer 1062 from being oxidized. In such an example, the metal layer 106 may finally comprise the seed layer 1061, the main metal layer 1062 and the anti-oxidation metal layer 1063. The metal layer 106 covers the entire back side 100B of the IC package structure 100 (the side to which the back surface 1026 of the IC chips or IC dies 102 are facing) and fills the opening 104V, so that the metal layer 106 is in direct contact with the exposed portions of the back surface 1026 of each IC chip/IC die 102 (i.e., the portions of the back surface 102B of each IC chip/IC die 102 that are not covered by the encapsulation layer 104). In an exemplary embodiment, the metal layer 106 may be formed to have a thickness of 10 μm to 2000 μm. In an alternative exemplary embodiment, the metal layer 106 may be formed to have a thickness of 50 μm to 1000 μm. In an alternative exemplary embodiment, the metal layer 106 may be formed to have a thickness of 100 μm to 500 μm. In still an alternative exemplary embodiment, the metal layer 106 may be formed to have a thickness of 100 μm to 200 μm. During the process of electroplating the metal layer 106, molecular bonding forms at the interface between the metal layer 106 and the back surface 102B of each IC chip/IC die 102, making the metal layer 106 tightly bonded to (not easy to fall off from) the back surface 102B of each IC chip/IC die 102. In addition, the direct contact between the metal layer 106 and the back surface 102B of each IC chip/IC die 102 may help to greatly enhance the heat dissipation capacity of the IC chip/IC die 102, and improve the heat dissipation performance of each IC chip/IC die 102.

Next, referring to the example of FIG. 2E, the carrier 201 is peeled off and the adhesive layer 202 is removed to expose the top surface 102T of each integrated circuit chip/die 102 and its metal pads 105. So far, a panel-shaped IC package structure 100 including a plurality of (at least one) integrated circuit chips/dies 102, an encapsulation layer 104, and a metal layer 106 is manufactured. The metal layer 106 located on the back side 100B of the panel-shaped IC packaging structure 100 can improve the heat dissipation performance of the packaged integrated circuit chip/chip 102. On the top side 100T of the panel level IC package structure 100, the top surface 102T of each IC chip or IC die 102 and its metal pads 105 are exposed, which allows the packaged IC chip or IC die 102 to interact with other external circuits or external structure or external components for electrical connection and/or signal communication.

For instance, referring to the example of FIG. 2F, the metal pad 105 of each integrated circuit chip/die 102 may be led out on the top side 100T of the panel-shaped IC package structure 100 through a rewiring process. For example, a rewiring structure 107 may be fabricated to lead out each integrated circuit chip/die 102. Those skilled in the art should understand that there are many methods for fabricating the rewiring structure 107, which are not limited or exhaustive in this application, and the following are only examples. The rewiring structure 107 may be fabricated by a method different from the following examples, which does not exceed the spirit and protection scope of the present invention.

In the example of FIG. 2F, a plating mask (for instance a dry film such as a polyimide film) may be formed on the exposed surface of the top side 100T of the panel-shaped IC package structure 100 under fabrication shown in FIG. 2E. One of ordinary skill in the art would understand that here, “on” does not specifically refer to on the upper side in the cross sectional views, because the top side 100T of the IC package structures 100 shown in 2E is facing down, but before the actual rewiring process, the panel-shaped IC package structure 100 will be flipped so that the top side 100T is facing upwards. Then, the plating mask may be patterned (for example, patterned by using laser direct imaging technology or other exposure and development techniques) to expose the metal pads 105. After that, the patterned plating mask may be used as a mask for forming a plurality of metal pillars 108 corresponding to each IC chip/IC die 102 for example by an electroplating process, with each one of the plurality of metal pillars 108 connected to a corresponding one of the plurality of metal pads 105. Subsequently, the plating mask may be removed and a first interlayer dielectric layer 1081 may be formed for example by a lamination (or rolling) process to fill all the gaps between the metal pillars 108. Optionally, according to an alternative exemplary embodiment, the first interlayer dielectric layer 1081 may be formed on the exposed surface of the top side 100T of the panel-shaped IC package structure 100 shown in FIG. 2E, and then the first interlayer dielectric layer 1081 may be patterned, for example, by a laser drilling process to expose the metal pads 105, and then the patterned first interlayer dielectric layer 1081 may be used as a mask for electroplating metal materials to form the metal pillars 108.

Similarly, a patterned plating mask may be further fabricated on the first interlayer dielectric layer 1081 according to practical application requirements, and then a first rewiring metal layer 1072 may be fabricated by electroplating with the patterned plating mask as a mask for the electroplating process. A person skilled in the art should understand that in order to form the first rewiring metal layer 1072 of irregular shape, it is possible to repeat the process of forming the plating mask, patterning the plating mask, and electroplating metal materials with the patterned plating mask as a mask for electroplating. After the first rewiring metal layer 1072 is made, the plating mask may be entirely removed, and then a second interlayer dielectric layer 1071 may be formed for example by a lamination (or rolling) process. The second interlayer dielectric layer 1071 may fill all the gaps between segments of the first rewiring metal layer 1072. Optionally, accordingly to an alternative embodiment, the second interlayer dielectric layer 1071 may firstly be formed on the first interlayer dielectric layer 1081, and then the second interlayer dielectric layer 1071 may be patterned, and subsequently the patterned second interlayer dielectric layer 1071 may be used as a mask for electroplating to form the first rewiring metal layer 1072.

It is also possible to further fabricate a patterned plating mask on the second interlayer dielectric layer 1071 according to practical application requirements, and then a second rewiring metal layer 1074 may be fabricated by electroplating metal materials with the patterned plating mask as a mask for the electroplating process. A person skilled in the art should understand that in order to form the second rewiring metal layer 1074 of irregular shape, it is possible to repeat the process of forming the plating mask, patterning the plating mask, and electroplating metal materials with the patterned plating mask as a mask for electroplating. After the second rewiring metal layer 1074 is made, the plating mask may be entirely removed, and then a third interlayer dielectric layer 1073 may be formed for example by a lamination (or rolling) process. The third interlayer dielectric layer 1073 may fill all the gaps between segments of the second rewiring metal layer 1074. Optionally, accordingly to an alternative embodiment, the third interlayer dielectric layer 1073 may firstly be formed on the second interlayer dielectric layer 1071, and then the third interlayer dielectric layer 1073 may be patterned, and subsequently the patterned third interlayer dielectric layer 1073 may be used as a mask for electroplating to form the second rewiring metal layer 1074, etc. Those skilled in the art should understand that the first interlayer dielectric layer 1081, the second interlayer dielectric layer 1071, and the third interlayer dielectric layer 1073 may comprise a same dielectric material, or may include different dielectric materials.

At last, the entire panel of the panel-shaped IC package structure 100 may be divided into a plurality of independent package units (for example, the singulated package units 101) by a cutting process. Each package unit 101 may include at least one integrated circuit chip/die 102, e.g. referring to the exemplary illustrations in FIG. 1B to FIG. 1E.

The present disclosure provides a package structure including at least one integrated circuit chip/die and a related method for manufacturing an integrated circuit chip/die. Although some embodiments of the present disclosure are described in detail, it should be understood that these embodiments are only for illustrative purposes. It is not intended to limit the scope of the present invention.

From the foregoing, it will be appreciated that specific embodiments of the present invention have been described herein for purposes of illustration, but that various modifications may be made without deviating from the invention. Many of the elements of one embodiment may be combined with other embodiments in addition to or in lieu of the elements of the other embodiments. Accordingly, the present invention is not limited except as by the appended claims.

What is claimed is:

1. An integrated circuit (“IC”) package structure, comprising:
an array of package units formed into a panel, wherein each one of the array of package units comprises at least one IC chip/IC die, and wherein each IC chip/IC die has a top surface and a back surface opposite to the top surface;
an encapsulation layer, filling gaps between the package units, at least partially covering and wrapping the at least one IC chip/IC die in each package unit, and having one or more openings at a portion corresponding to the back surface of each IC chip/IC die to expose entire or at least a portion of the back surface of each IC chip/IC die; and
a metal layer, electroplated on entire back side of the IC package structure and filling the openings in the encapsulation layer so that the metal layer is in direct contact with the exposed portions of the back surface of each IC chip/IC die, wherein the back side of the IC package structure refers to the side to which the back surface of each IC chip/IC die is facing.

2. The IC package structure of claim 1, wherein the array of package units comprises an array of M rows by N columns, wherein M and N are both positive integers greater than or equal to 1.

3. The IC package structure of claim 1, wherein the panel is of a size chosen from 300 mm*300 mm, 580 mm*600 mm, 800 mm*800 mm, 240 mm*74 mm, 189 mm*68 mm.

4. The IC package structure of claim 1, wherein a relatively large opening is formed in portions of the encapsulation layer above each IC chip/IC die to expose entire or most of the back surface of each IC chip/IC die.

5. The IC package structure of claim 1, wherein a plurality of relatively small openings are formed in portions of the encapsulation layer above each IC chip/IC die to expose a corresponding plurality of portions of the back surface of each IC chip/IC die.

6. The IC package structure of claim 1, wherein before the metal layer is electroplated, the entire back surface of encapsulation layer is grounded/polished until the entire back surface of each IC chip/IC die is exposed.

7. The IC package structure of claim 1, wherein each IC chip/IC die has a plurality of metal pads formed on its top surface.

8. The IC package structure of claim 7, further comprising:
a rewiring structure to lead out the plurality of metal pads of each IC chip/IC die so that each IC chip/IC die is eligible to be electrically coupled to external circuits or for signal communication.

9. The IC package structure of claim 1, wherein the metal layer comprises an electroplated copper layer.

10. The IC package structure of claim 9, wherein the metal layer further comprises a conductive seed layer under the electroplated copper layer.

11. An integrated circuit (“IC”) package unit, comprising:
at least one IC chip/IC die, each of the at least one IC chip/IC die having a top surface and a back surface opposite to the top surface;
an encapsulation layer, filling the IC package unit to at least partially cover and wrap the at least one IC chip/IC die, and having one or more openings at a portion corresponding to the back surface of each IC chip/IC die to expose entire or at least a portion of the back surface of each IC chip/IC die; and
a metal layer, electroplated on entire back side of the IC package unit and filling the openings in the encapsulation layer so that the metal layer is in direct contact with the exposed portions of the back surface of each IC chip/IC die, wherein the back side of the IC package unit refers to the side to which the back surface of the IC chip/IC die is facing.

12. The IC package unit of claim 11, wherein a relatively large opening is formed in portions of the encapsulation layer above each IC chip/IC die to expose entire or most of the back surface of each IC chip/IC die.

13. The IC package unit of claim 11, wherein a plurality of relatively small openings are formed in portions of the encapsulation layer above each IC chip/IC die to expose a corresponding plurality of portions of the back surface of each IC chip/IC die.

14. The IC package unit of claim 11, wherein before the metal layer is electroplated, the entire back surface of encapsulation layer is grounded/polished until the entire back surface of each IC chip/IC die is exposed.

15. The IC package unit of claim 11, wherein each IC chip/IC die has a plurality of metal pads formed on its top surface.

16. The IC package unit of claim 15, further comprising.
a rewiring structure to lead out the plurality of metal pads of each IC chip/IC die so that each IC chip/IC die is eligible to be electrically coupled to external circuits or for signal communication.

17. The IC package unit of claim 11, wherein the metal layer comprises an electroplated copper layer.

18. The IC package unit of claim 17, wherein the metal layer further comprises a conductive seed layer under the electroplated copper layer.

19. A method for manufacturing an integrated circuit (“IC”) package structure, comprising:
attaching a plurality of IC chips/IC dies to be packaged on a carrier;
forming an encapsulation layer to fill gaps/spaces between the plurality of IC chips/IC dies, and cover and wrap the plurality of IC chips/IC dies;
removing at least a portion of the encapsulation layer above each IC chip/IC die to form one or more openings to expose entirety or at least a portion of a back surface of each IC chip/IC die;
forming a seed layer on the encapsulation layer and the exposed portions of the back surface of each IC chip/IC die; and
electroplating metal materials on the seed layer to form a metal layer which is in direct contact with the exposed portions of the back surface of each IC chip/IC die.

20. The method of claim 19, further comprising:
removing the carrier to expose a top surface of each IC chip/IC die having a plurality of metal pads formed on the top surface; and
forming a rewiring structure to lead out the plurality of metal pads of each IC chip/IC die so that each IC chip/IC die is eligible to be electrically coupled to external circuits or for signal communication.
